(19) United States
(12) Patent Application Publication
(10) Pub. No.: US 2025/0371399 A1
(43) Pub. Date: Dec. 4, 2025

(54) METHOD AND SYSTEM FOR PREPARING QUANTUM DOTS FOR QUANTUM COMPUTATION

(71) Applicant: SOCPRA SCIENCES ET GENIE S.E.C., Sherbrooke (CA)

(72) Inventors: Pierre LEFLOIC, Sherbrooke (CA); Michel PIORO-LADRIÈRE, Sherbrooke (CA); Zhiren WANG, Bagneux (FR)

(21) Appl. No.: 19/127,791

(22) PCT Filed: Nov. 18, 2022
(86) PCT No.: PCT/CA2022/051704

§ 371 Date: May 7, 2025

Related U.S. Application Data
(60) Provisional application No. 63/424,498, filed on Nov. 11, 2022.

(51) Int. Cl. G06N 10/40; H10K 50/115

(52) U.S. Cl. CPC G06N 10/40; H10K 50/115

(57) ABSTRACT

The method can include providing a semiconductor material having a band gap associated to an energy difference; preparing a first quantum dot, including propagating an electromagnetic wave having an energy greater than the energy difference into the semiconductor material, the electromagnetic wave separating an electron of the semiconductor material from a hole of the semiconductor material in the presence of an electromagnetic field, the electromagnetic field maintaining the electron separated from the hole, and maintaining at least one of the separated electron and the separated hole confined within the semiconductor material; the first quantum dot engaging in a quantum interaction with a second quantum dot; and measuring a quantum state of the first quantum dot and of the second quantum dot.

### BACKGROUND

Quantum systems, i.e. systems which harness the quantum properties of matter for human use, have received significant research and development interest and activity in the last years and are expected to become more and more mainstream within the next decades. A lot of this new interest is tied to the immense potential of the technology, in particular in relation with quantum computing and computerized communication security, but also in relation with other significant areas of interest.

The basic concept of performing a computation in a quantum context typically involves a quantum interaction such as entanglement between quantum subsystems such as qubits. Indeed, in a process of quantum computation, information can be encoded in the form of eigenstates of quantum subsystems. Particular hardware and complex control schemes, typically encoded as software functions and executed by a classical computer, are typically required. Moreover, the quantum behavior is currently exhibited in a cryogenic environment, such as below 100 K, 50 K, 10 K or even lower, depending on the architecture, although research for quantum systems operable at higher temperatures is a highly active area of current research. Different types of quantum subsystem hardware which can host qubits exist, and the selection thereof depends on the nature of the quantum subsystem. Examples of physical particles which can exhibit quantum behavior at the subatomic level includes electrons, for which the state of the spin can be used to encode quantum information (e.g. spin up vs. spin down) and photons, for which the state of the polarization can be used to encode quantum information (e.g. vertical polarization vs. horizontal polarization), but other approaches exist such as phonon-based approaches or cold atom/ion based approaches. Quantum mechanics allows the qubit to be in a coherent superposition of both states simultaneously, a property which is fundamental to quantum computing.

Different forms of quantum computing exist, which typically involves using two or more quantum subsystems interconnected to one another in a manner to allow quantum interaction. In quantum annealing, a specific problem is posed in the form of a configuration of interconnection between quantum subsystems which can communicate directly with one another, and the solution to the problem appears in the form of a base state of the overall system. In gate-based quantum computing, which can provide a “universal” computing approach, couplers are used to selectively allow or prevent the interaction between corresponding quantum subsystems. In gate-based quantum computing, quantum interaction control can involve two aspects, or facets: i) stimulating the interaction on demand, and ii) avoiding undesired interactions from spontaneously occurring due to quantum effects. Other forms of quantum computing applications can include quantum communication routers, for instance.

Performing a given instance of a quantum computation typically involves three main steps: 1) initializing, 2) interacting and 3) measuring. The step of initializing typically involves controlling the quantum state of the quantum subsystems prior to the step of interacting, in a manner to allow information to be associated with corresponding quantum subsystems. The step of interacting typically involves allowing the quantum states of at least two qubits to perform a quantum interaction, such as entanglement, with one another, which can change the state of the qubits. Indeed, during a quantum interaction, the states of the participating quantum subsystems can be correctly described by a wave equation which spans both quantum subsystems. The step of interacting is actively controlled via couplers in gate-based models whereas it occurs naturally in annealing based models. The step of measuring, commonly referred to as “readout”, typically involves determining the state in which the quantum subsystems are in subsequently to the interaction. The hardware and process steps required to perform either one of these steps depends on the type of architecture.

Indeed, the exact nature of the quantum subsystems and of any couplers will vary depending on the type of quantum architectures in which they are implemented. Various architectures have been developed in recent years, such as architectures based on superconducting circuits, quantum dots, trapped ions, photonic circuits, phonons, cold atoms, and hybrid approaches. Some architectures are perceived as more promising than others but the overall maturity of the field is such that breakthrough, game-changing innovations are expected to continue to occur. It will be understood that while existing hardware and process steps have led to the relatively intense level of international excitement about the possibilities opened up via quantum computing, there remains much room for improvement, and many further developments will be required before quantum computers can be offered in the form of consumer products.

### SUMMARY

In accordance with one aspect, there is provided a method of performing a quantum computation comprising: providing a semiconductor material having a band gap associated to an energy difference; preparing a first quantum dot, including propagating an electromagnetic wave having an energy greater than the energy difference into the semiconductor material, the electromagnetic wave separating an electron of the semiconductor material from a hole of the semiconductor material in the presence of an electromagnetic field, the electromagnetic field maintaining the electron separated from the hole, and maintaining at least one of the separated electron and the separated hole confined within the semiconductor material; the first quantum dot engaging in a quantum interaction with a second quantum dot; and measuring a quantum state of the first quantum dot and of the second quantum dot.

In accordance with another aspect, there is provided a system comprising a semiconductor material having a band gap associated to an energy difference, the semiconductor material having at least a first quantum dot region and a second quantum dot region, the semiconductor material having a planar geometry; a confinement barrier covering both the first quantum dot region and the second quantum dot region; an emitter system configured for emitting an electromagnetic wave having an energy greater than the energy difference into the semiconductor material, at the first quantum dot region and at the second quantum dot region, across the confinement barrier; means of sustaining an electromagnetic field in both the first quantum dot region and the second quantum dot region; a quantum tunneling barrier between the first quantum dot region and the second quantum dot region; means of measuring a quantum state of the first quantum dot region and of the second quantum dot region.

Many further features and combinations thereof concerning the present improvements will appear to those skilled in the art following a reading of the instant disclosure.

### DESCRIPTION OF THE FIGURES

In the figures,

FIG. 1 is schematic view of a quantum computer in accordance with one example;

FIG. 2 is a process chart representing a process of performing a quantum computation in accordance with one example;

FIG. 3 is a schematic view of a device configured for use as a quantum dot;

FIG. 3a is a schematic representation of a band structure for a device such as the device of FIG. 3 with an electromagnetic field having a first polarity;

FIG. 3b is a schematic representation of a band structure for a device such as the device of FIG. 3 with an electromagnetic field having a second polarity;

FIG. 4 is a schematic view of a system of quantum dots in accordance with a first embodiment;

FIG. 5 is a schematic view of a system of quantum dots in accordance with a second embodiment;

FIG. 6 is a schematic view of a heterostructure used for a device in accordance with another embodiment;

FIG. 7 is a schematic representation of a housing structure for a device, in accordance one embodiment;

FIG. 8c is a schematic representation of a device in accordance with one example embodiment, wherein the device can be housed in the housing structure of FIG. 7, and FIGS. 8b and 8a are successively enlarged portions of the device of FIG. 8c;

FIGS. 9a and 9b are SEM images of a device constructed in accordance with the schematic of FIG. 8 where a) shows two plunger gates separated by the tunnel barrier gate and the resonator gate on the left and b) shows the mesa edge, the whole mesa being visible in the inset.

FIGS. 10a and 10b present the effect of illumination of the device of FIGS. 7a and 7b on the stability diagram with a) a stability diagram around (V_L,V_R)=(0,0) V before any illumination and b) showing the same diagram, but after a 10 s illumination;

FIG. 11 presents a stability diagram of a double quantum dot with addition lines indicated in dashed lines. The inset shows the three distinct types of lines: the two addition lines (green and orange) and the interdot line (purple);

### DETAILED DESCRIPTION

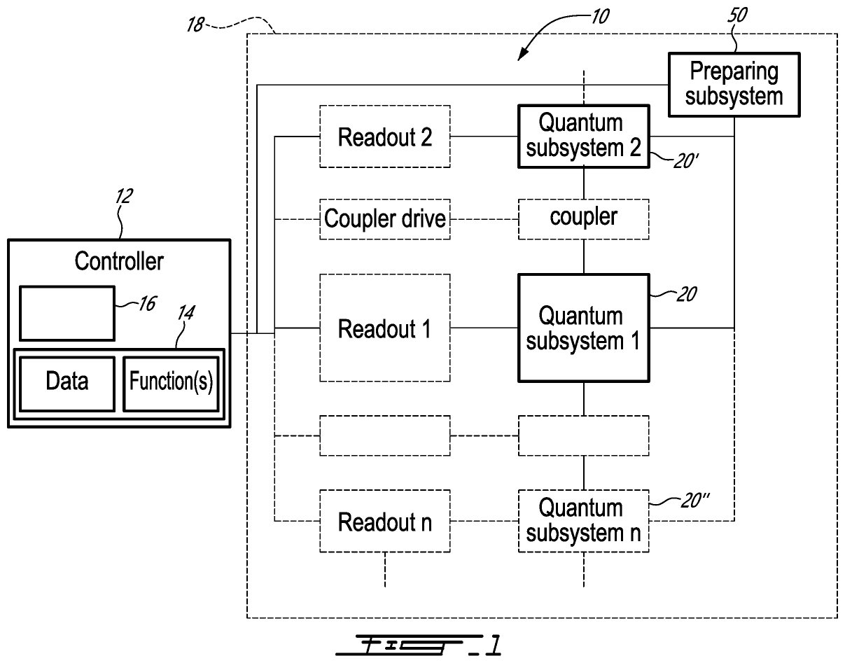

FIG. 1 presents a schematic example of a quantum system 10 which includes a plurality of quantum subsystems 20, 20′, 20″. In this example, the quantum subsystems 20, 20′, 20″use quantum dots to host qubits, and can therefore be referred to as being of a quantum dot architecture. In the context of quantum computing, the quantum subsystems 20, 20′, 20″ are used to host logical states (referred to as qubits in this context), and the quantum system 10 can used as part of a quantum processor. The nature of the qubits, the means by which logical states are hosted in the qubits, and the means by which operations are performed can vary based on implementation details of a specific embodiment.

Performing a quantum computation can involve a quantum interaction, such as entanglement, between the physical states (which encode information) of the different quantum subsystems. However, for a quantum computation to occur, one may further actively initialize the physical states of the quantum subsystems prior to the quantum interaction (e.g. control the physical state of the quantum subsystems), and actively measure the physical states subsequently to the quantum interaction. Moreover, when performing a quantum computation in a gate-based model, one may additionally actively control the interaction via a coupler which is changed from a configuration where it impedes interaction to a configuration where it favors interaction, and then back.

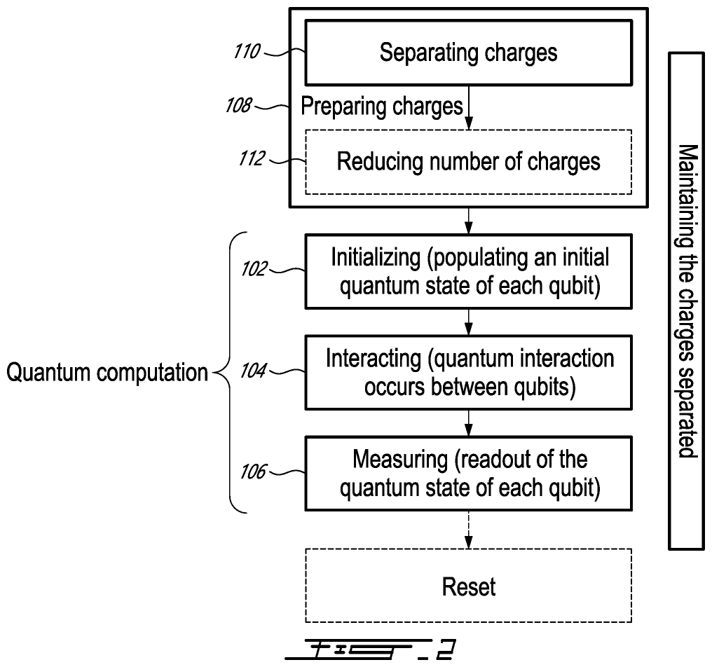

Henceforth, as schematically represented in FIG. 2, performing a given quantum computation can involve these three steps: initializing 102, interacting 104, and measuring 106. Moreover, as presented in FIG. 2, in embodiments presented herein, a quantum computation can further include a “preparing” step 108 in which the charges are actively made available in a state adapted to quantum computation at corresponding quantum dots. In embodiments presented in greater detail below, the step of “preparing” involves separating 110 charges, more specifically here electrons from electron holes, via the application of electromagnetic waves (e.g. light) of a suitable energy at corresponding ones of the quantum subsystems. Accordingly, any of the steps of preparing 108, initializing 102, interacting 104 and measuring 106 may have corresponding hardware elements and an active control process associated therewith.

Any active control step may require associated elements of hardware. Moreover, it can be impossible to manually control the hardware associated with the active control steps in a context of the amount of time available to perform any one of these steps. Accordingly, automated control can be essential to implement the active control steps. The automated control processes can take the form of associated functions defined by corresponding software modules. Accordingly, several elements of hardware, such as preparing hardware, initializing hardware, coupler control hardware and measuring hardware, may involve automated, active control in the context of performing a single quantum computation. The control functions for such hardware elements are be performed via a component which will be referred to herein as a controller 12 for simplicity, and which can involve a “classical” computer (i.e. a computer which uses binary bits rather than qubits to encode information).

Referring back to FIG. 1, an example controller 12 is shown. The controller 12 can include a processor 16 and a non-transitory memory 14 which can include functions in the form of computer readable instructions executable by a classical processor of the controller to drive the operation of the quantum processor, and data. The data can include definitions of different possible logical states of the different qubits, for instance. The functions can include a “driving program”, for instance, which, in the case of gate-based quantum computing, can include a sequence of gates, typically referred to as a quantum circuit, stored as data in the memory, and governing the control of the step of “interacting”. When the state of the qubits are “read”, following the step of “interacting”, the measured values can be stored in the form of data, for instance. The controller 12 can also include a user interface.

The components of the quantum processor 10, such as the quantum subsystems 20, 20′, 20″ and some or all of the control hardware, are typically refrigerated to very low temperatures and insulated from the environment, and can therefore be said to be inside a “refrigerator” 18, which can be a dilution refrigerator for instance. Components of the classical computer such as its processor 16 and its non-transitory memory 14 can be located outside the refrigerator. Electrical connections can therefore extend across an enclosure of the refrigerator, between the ambient temperature environment and the cryogenic environment. The combination of the classical computer, of the quantum processor 10, of the electrical connections, and of the refrigerator 12, can be referred to collectively as a “quantum computer”.

While a simplistic scenario having a minimum of 2 quantum subsystems 20, 20′ is schematized in solid lines in FIG. 1, in practice, it can be preferred to embody quantum computers with a significantly greater number of quantum subsystems 20, 20′, 20″, or qubits, which can significantly affect the complexity of the overall system, both from the hardware and from the control process points of view.

In the example presented in FIG. 1, the quantum subsystems 20, 20′, 20″ can be embodied in a quantum dot-based architecture. In quantum dot-based architecture, electrons (or electron holes) are used as a physical media to encode quantum information. Depending on the exact details of implementation, the quantum information can be encoded in the spin orientation, or in the location (e.g. presence or absence of a charge at a particular location), to name some examples. A quantum dot-based architecture typically involves the physical control of individual electrons (or sometimes equivalently electron holes), or of sufficiently small groups of electrons (or electron holes) for the groups to exhibit quantum behavior, any of which can be referred to as a “charge” herein for simplicity and convenience.

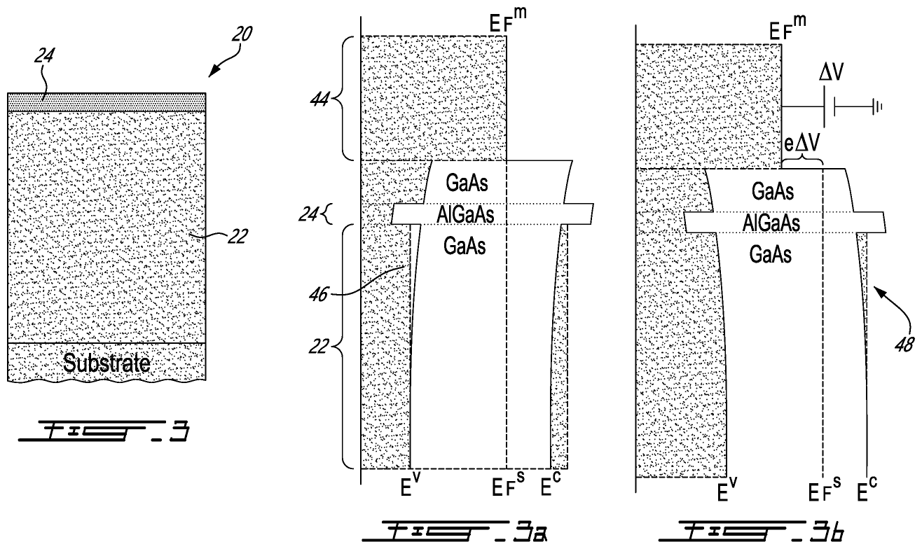

Referring to FIG. 3, hardware associated to a single quantum dot-based quantum subsystem 20 is presented in accordance with one example embodiment. In this embodiment, the hardware includes a component which will be referred to as a channel 22 herein, and which has a given volume of a semiconductor material. The selection of the semiconductor material can be based on the exact implementation details, and different semiconductors may be used, such as gallium arsenide (GaAs), silicon, and germanium for instance. The semiconductor material has a band gap, sometimes alternately referred to as an energy gap, in the form of an energy range without electronic states. The band gap has an associated energy difference, defined as the difference in energies defining the boundaries of the band gap. The energy difference can be embodied as a difference in energy between a “conduction band” and a “valence band”, as known in the art.

A first control hardware element which can be used is a confinement barrier 24. A confinement barrier 24 can be implemented as a passive control hardware element. In the embodiment presented in FIG. 3, a confinement barrier 24 can be implemented as a layer of material which covers or otherwise overlays the channel 22. The purpose of the confinement barrier 24 can be to prevent separated charges from exiting the semiconductor material. One example way to implement a confinement barrier 24 is to use a layer of a semiconductor material which has a band gap greater than the band gap of the semiconductor material forming the channel 22. Another example way to implement a confinement barrier is to use a layer of an oxide material. Various configurations are possible. Moreover, in some cases, it can be preferred to use more than one confinement barrier, e.g. to confine the charges in more than one direction. Indeed, a quantum well can use two parallel barriers sandwiching the channel, with a charge gas configuration being a variant of the quantum well configuration wherein the channel is sufficiently thin between the two confinement barriers for the charges to be virtually confined to a 2D plane. The use of one or more confinement barriers can play a role in each one of the three functions in some embodiments. In the example of FIG. 3, the confinement barrier 24 can be embodied in the form of a semiconducting barrier layer. Alternately, an oxide layer may be used, but in some cases, an oxide layer can be deemed to interfere with the transmission of electromagnetic waves into the channel at the preparation step and for such reasons, using a semiconducting material may be preferred.

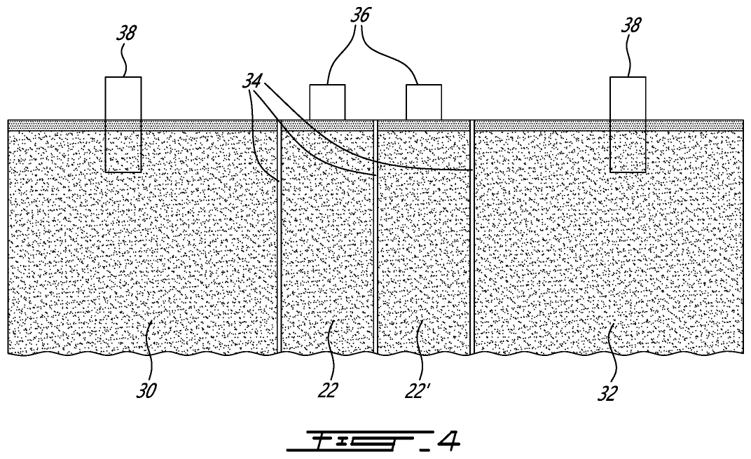

There are different possible approaches to providing the charges associated to a quantum dot. In accordance with a first example approach, the semiconductor material of the channel can be intentionally doped a “dopant” which provides excess charges. If the excess charges are electrons, the material can be referred to as n-doped, whereas if the excess charges are holes, the material can be referred to as p-doped. The dopants used can be “shallow” donors of charge which allow the excess charges to circulate within the material. Using so “doped” semiconductor material as a base material to host the quantum dots, quantum dots can be provided such as schematized in FIG. 4.

Indeed, as shown in FIG. 4, a plurality of quantum dots 20, 20′ can be interconnected with one another and interconnected between a source 30 and a drain 3230. Gates, such as tunnelling barrier gates 34, can provide selective connectivity between adjacent ones of the elements 20, 20′, 30, 32 of the system. Electrostatic contacts 36 can be provided as means of imparting an electromagnetic field (in this case, the expression electric field would be more precise since there is no magnetic component, but the expression electromagnetic will be used herein to refer to either one or both an electric field and a magnetic field) into corresponding ones of the quantum subsystems 20, 20′, which can have the effect of limiting the available “space” for excess charges within each quantum dot (sometimes referred to as adjusting the “size” of the quantum dots). Ohmic contacts 38 can be used at the source 30 and the drain 32, as a means of adding or subtracting charges into or from the system. While such a configuration can be useful to a certain degree, there remained room for improvement. In particular, any contact or gate may require some degree of physical space, and so do the drain and the source. The physical space occupied by such elements may limit the scalability of the system. For instance, the presence of contacts, source and/or drain may prevent one from achieving a practical 2D array of quantum dots for instance and such a configuration may be limited to a 1D array. Moreover, Ohmic contacts can be challenging to produce and therefore be associated to an undesirable source of costs. Moreover, introducing the dopants into the semiconductor structure, while possible, can represent an additional doping step at the time of manufacture which can represent a certain level of challenge and another undesirable source of costs.

In accordance with a second example approach, the charges associated to a quantum dot can be made available by separating electrons from holes using the energy of electromagnetic waves, in a process step which will be referred to herein as “preparing the quantum dot” 108 with reference to FIG. 2.

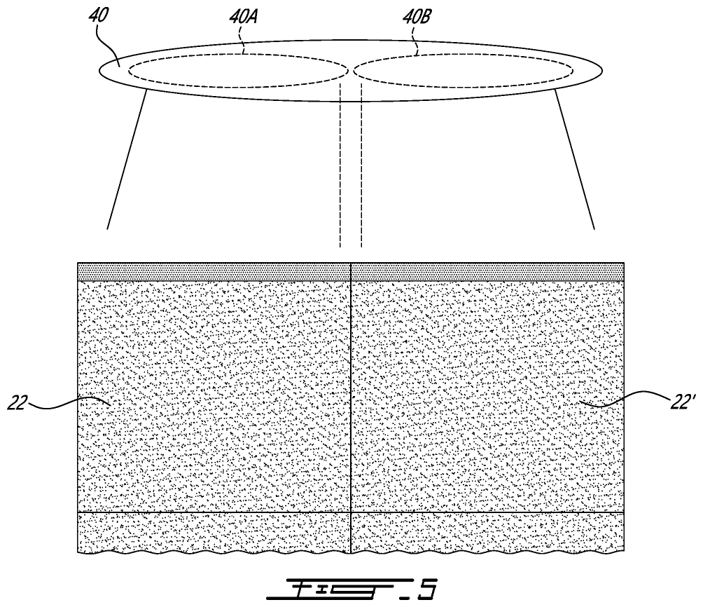

Indeed, as presented schematically in FIG. 5, a plurality of quantum dots 20, 20′ can be interconnected with one another, and prepared via the use of electromagnetic waves emitted by one form or another of an electromagnetic wave emitter 40. In this context, the channel does not inherently require a “shallow donor dopant”. Rather, the charges can be provided by separating electrons from electron holes in the semiconducting material of the channel itself. More specifically, the charges can be separated by imparting into the semiconducting material, electromagnetic waves of an energy greater than the energy difference associated to the band gap. Depending on the nature of the material forming the channel, such electromagnetic waves may be achieved with infrared (IR) light for instance, or other forms of light such as visible light or even ultraviolet (UV) light may be possible in alternate embodiments. Once the charges have been separated by absorbing the energy of the electromagnetic wave(s), they can be maintained in a separated state, while performing the quantum computation, by an electromagnetic field. While the use of an electrostatic contact is one way of implementing such an electromagnetic field, it will be noted that other ways exist. For instance, an electromagnetic field can be imparted inherently into the material of the channel by the presence of “deep” donor dopants, which may have been placed into the semiconducting material intentionally, or simply be there by default.

There are many types of what we will refer to here as “defects” in relation to the crystalline structure, which can have the effect of doping a semiconductor material with charges (electrons or electron-holes), and which can therefore alternately be referred to as dopants. In some cases, the defects can be engineered, such as by the voluntary addition of atoms of a given material into the crystalline structure, with the intent of causing a particular doping effect. In other cases, the defects can be present naturally. The nature of any naturally occurring defects which act as dopants can vary depending on many variables such as the nature of the semiconductor material or other materials used in the device structure, the type of growth process, and even parameters of the growth process such as temperature, concentration, growth rate, material purity, etc.

In the case of GaAs, to serve as one example of a semiconductor material, Martin et al., Electron Traps in Bulk and Epitaxial GaAs Crystals, Electronic Letters, 31 Mar. 1977, Vol. 13, no. 7 presents an analysis of defects causing additional electrons, whereas Mitonneau et al., Hole Traps in Bulk and Epitaxial GaAs Crystals, Electronic Letters, Oct. 27, 1977, Vol 13, No. 22 presents an analysis of defects causing additional holes. The nature of defects associated with other types of semiconductor materials can be similarly complex and detailed in associated studies.

Defects can be categorized in the following types:
Vacancy defects: an atom of the crystalline structure is absent.
Interstitial defects: an atom is present in the crystal at a location where no atom should be present.
Substitutional defects: an atom foreign to the crystalline structure substitutes an atom of the crystalline structure.
Antisite defects: a first atom of the crystalline structure substitutes a second atom of the crystalline structure.

Semiconductor materials are typically engineered for use at a given temperature of use in a specific application or context. In this specification, dopants will be referred to as “shallow donors of charge” when their ionization energy (energy required to separate the charge) is lower than the thermal energy at the temperature of use (i.e. they typically ionized naturally due to thermal energy at the temperature of use). Conversely, dopants will be referred to as “deep donors of charge” when their ionization energy is higher than the thermal energy at the temperature of use (i.e. they typically would not ionize solely due to thermal energy at the temperature of use). In quantum computing, the temperature of use is typically cryogenic. It will be noted that while in some circumstances, defects providing excess electrons can be referred to as donors and defects providing excess electron holes can be referred to as acceptors, the expression “donors” (of charge) will be used herein to refer to both in a context where the charges can be either electrons or electron holes.

FIG. 3a schematically presents a band structure of a device having a structure similar to the one of FIG. 3. The abrupt change of the band at the interface between the metal 44 and the semiconductor is the Shottky barrier. In this embodiment, the visible bending is the result of native point defects, more specifically type-n, or excess electron, deep donor dopants. A similar effect can be achieved by the application of an electric field of a first polarity, e.g. by applying a negative bias on the metallic gate. This forms a trap for holes 46 under the barrier. In an alternate embodiment, a band structure such as the one presented in FIG. 3b for instance, which forms an electron trap 48, instead of a trap for electron holes, can be achieved. Such a band structure can be achieved via type-p, or excess electron hole, deep donor dopants, or by the application of an electric field of a second polarity, e.g. by applying a positive bias (e.g. AV) on the metallic gate 44. Accordingly, both the band structures shown in FIG. 3a and in FIG. 3b present a trap which can receive a charge which can be used as a quantum dot for the purpose of quantum computing. In this example, the Shottky potential goes deep inside the structure, reaching bellow the barrier, creating a potential well for holes. The figure is not to scale and represent an embodiment where the barrier layer 24 is covered by a protective layer. The protective layer, between the metal 44 and the barrier 24, would appear much thinner than the barrier 24 if the figure was to scale.

In the embodiment of FIG. 5, it will be noted that a source and a drain, together with the associated Ohmic contacts, can be omitted, and there can be a significant advantage to omitting such elements in the context of quantum computing as explained above. Moreover, while the presence of shallow donor dopants may not represent a significant issue, there can be a significant advantage to the fact that such shallow donor dopants can be not required in this case, as the step of doping the semiconductor with a shallow donor dopant can be omitted at the time of manufacture. Moreover, the possibility of using the presence of deep donor dopants to maintain the charge separation after the initial step of separating the charges with an electromagnetic wave can also be useful in some embodiments. Depending on the details of implementation of particular embodiments, either one of such advantages, or more than one of such advantages, may be harnessed by a designer, as found suitable in the context.

It will be noted that the presence of deep donor dopants, or other configurations imparting an inherent electromagnetic field in the channel, may pose a challenge in some embodiments however. Indeed, in some contexts of quantum computation, it can be required to allow resetting the charges between instances of quantum computation, i.e. recombining electrons with electron holes in a manner that no free charges remain present for a given period of time or at a given process step. It will be understood that in some embodiments, such a “resetting” step can represent a potential issue in a context where the channel has an inherent electromagnetic field. It was found however that at least in some embodiments, this re-setting can be achieved notwithstanding the presence of an inherent electromagnetic field, via the actively controlled application of an external electromagnetic field such as can be applied for instance via an electrostatic contact. An example will be presented in further detail below.

Referring back to FIG. 1, the “preparing” 108 can be performed via hardware elements which can be referred to herein as a “preparing subsystem” 50. The preparing subsystem 50 can include hardware elements associated to the operation of separating electrons from holes and which can include one (e.g. emitter 40 in FIG. 5) or more (e.g. emitters 40A and 40B in FIG. 5) emitters of electromagnetic radiation (e.g. visible, ultraviolet (UV), or infrared (IR) “light”) is configured for propagating electromagnetic radiation onto semiconductor material associated to the quantum dots. Indeed, in one possible embodiment, all the quantum dots can be uniformly illuminated with suitable electromagnetic radiation using a single electromagnetic radiation emitter 40. In another possible embodiment, different electromagnetic radiation emitters 40A, 40B may be associated to different ones of the quantum dots.

Depending on the embodiment, the initial step 110 of separating the charges may yield a satisfactory number of charges (e.g. a single photon creating a single charge or the number of charges otherwise being limited/controlled), or an excessive number of charges. If the initial step of separating 110 the charges yields an excessive number of charges, it may be relevant to follow through with a step 112 of reducing the number of charges prior to the step of initializing 102. Such a reduction in the number of charges can be performed by applying an electromagnetic field across the channel for instance. Accordingly, in embodiments where the initial step of separating yields an excessive number of charges, the preparing subsystem 50 can further include hardware elements associated to the step of reducing the number of charges. Such hardware elements can be specific to this function, or be shared with other functions, depending on the embodiment. In embodiments where the initial step of separating yields a satisfactory number of charges, the step of reducing the number of charges, together with any hardware element which would otherwise be specifically associated to this function, can be omitted.

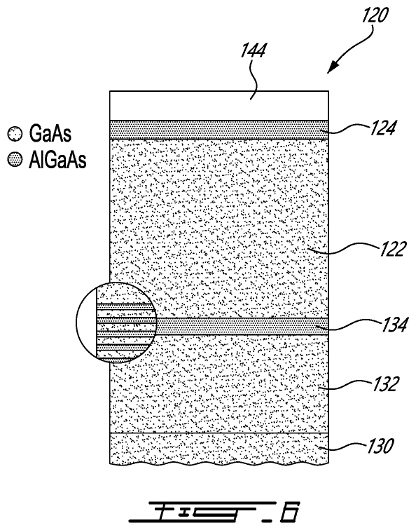

An example embodiment of hardware associated to the hosting of a quantum dot pair will now be presented with reference to FIGS. 6 to 9. This embodiment is presented for the purpose of providing a demonstration, and ensuring a complete description, although it will be understood that this example is intended to be only one possible example, and not to limit the general applicability of the concepts presented herein. In this embodiment, it was found that the rapid growth in the number of control gates of gate-defined quantum dot systems could be tackled by a scheme in which the quantum dots are created from charges generated by electromagnetic waves and trapped beneath accumulation gates and beneath the barrier.

More specifically, an example heterostructure 120 which can be used used for such a device is presented in FIG. 6. A first significant layer is the AlGaAs barrier 124. This barrier 124 is used to create the (vertical) confinement used to form the quantum dots. Also, the barrier 124 is made thin enough to allow the light to reach below. More specifically a thickness of 50 nm is considered suitable in this embodiment.

A second significant layer is the channel 122, the active layer of the structure 120. This is where the charges are created by the light. In this embodiment, a metallic gate 144 deposited on top of the structure 120 can be used to generate an electromagnetic field in the device. One of the two polarities (either an electron or a hole) is attracted by the metallic gate 144, but it cannot travel through the AlGaAs barrier, so it stays trapped at the interface.

In this example, there is no intentionally added doping in the whole structure, although some residual doping stemming from defects acting as deep donor dopants may remain present. Such defects allow the Shottky potential formed by the metal gates to be finite and reach below the AlGaAs barrier, therefore also contributing to the attractive potential of the gates.

FIG. 6 presents one specific example embodiment where optional additional layers are also present. More specifically, in the example of FIG. 6, the channel layer 122 can be a 548 nm layer of GaAs, the barrier layer 124 can be a 50 nm layer of AlGaAs, and the substrate 130 is also of GaAs. In the example embodiment of FIG. 6, a buffer layer 132 of GaAs is present on top of the substrate 130, and a “superlattice” structure 134, consisting here of 10 layers alternating between GaAs and AlGaAs is on top of the buffer layer 132. The use of a superlattice structure 134 can help limiting the amount of defects in the substrate layer 130 which are able to migrate into the channel layer 122 during the growth of the latter, during fabrication, for instance. Both the substrate layer 132 and the buffer layer 132 can be GaAs.

In one example embodiment, a heterostructure 20, 120 having GaAs as the semiconductor material can be fabricated via metalorganic vapor-phase epitaxy (MOVPE) to name one potential example. In such a scenario, EL2 defects, associated to the presence of an Arsenic atom which replaces a Gallium atom in the crystalline structure, can form a deep donor dopant, and may naturally occur in a concentration sufficient to impart an electromagnetic field which can keep electrons separated from holes after they have been initially separated by the energy of the electromagnetic wave. In such a specific case, EL2 defects are likely to be a main source of such native point defects and has an effect such as exhibited in FIG. 6a, however, it will be understood that the type of defect present varies significantly depending on the type of material being used, the fabrication process, etc.

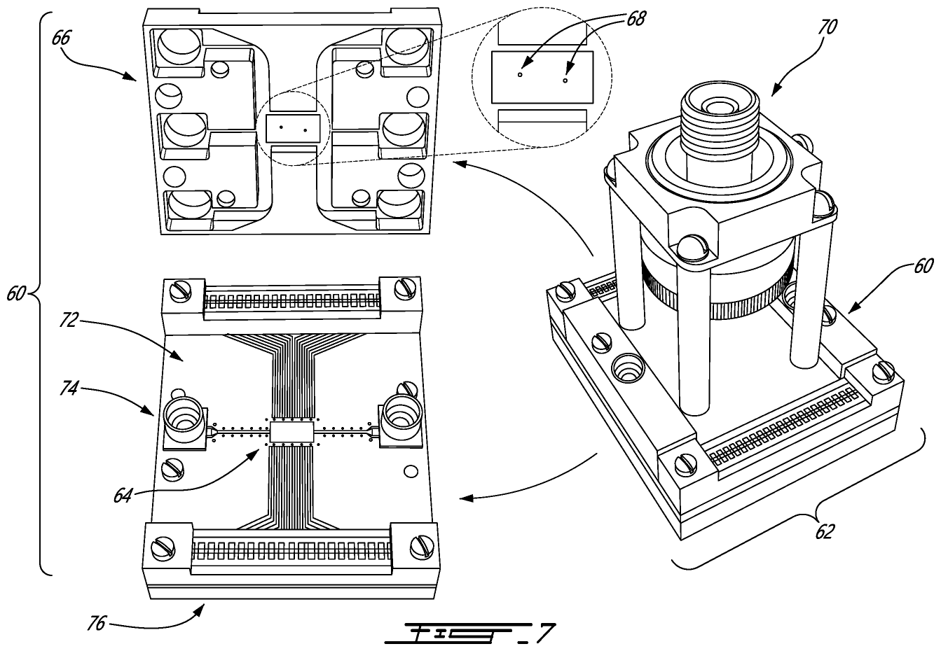

FIG. 7 presents an example of a housing 60 which can be used to house a device based on the heterostructure presented in FIG. 6. In this particular embodiment, the housing 60 has a microwave cavity 62 in which a device 64 bearing the quantum subsystems 20, 20′, is housed. The microwave cavity 62 can be opened by removing a cover 66 having pinholes 68 for electromagnetic radiation and supporting a collimator 70 in optical alignment with the pinholes 68. A printed circuit board (PCB) 72 is received within the microwave cavity 62 and configured to receive the device 64. A RF port 74 and a continuous current port 76 can also by provided.

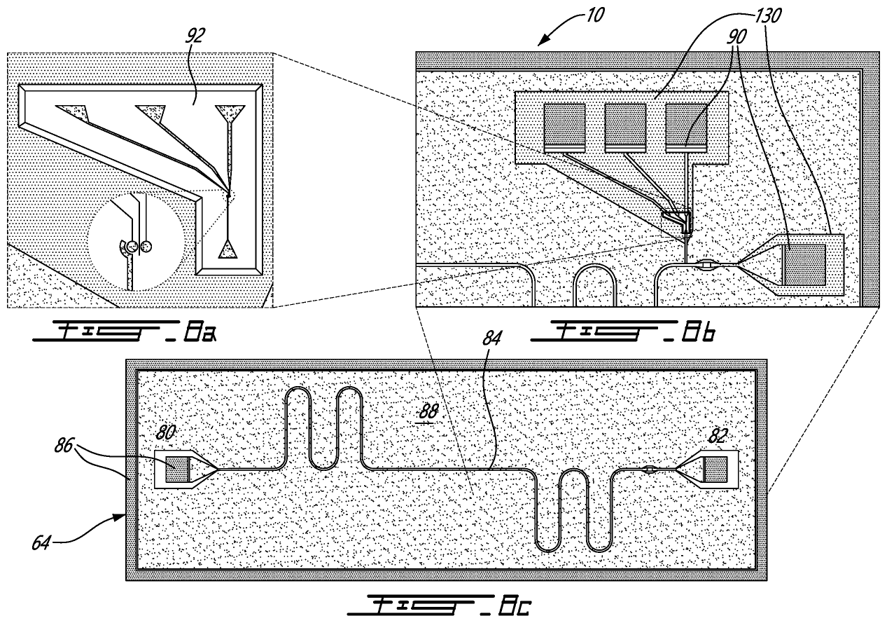

FIG. 8c presents the device 64 in accordance with the embodiment. The device 64 can be seen to have an entry port 80 connected to an exit port 82 by a central conductor 84 disposed relative a ground plane 88. A contact surrounds the ground plane 88, and contacts are associated to the entry port 80 and to the exit port 82. The ground plane 88 and conductor 84 can be of Niobium and the contacts 86 can be gold, for instance.

Interconnectors 90 can be provided at the interface between gold contacts 86 and niobium conductors 84. As shown in FIGS. 8a and 8b, a mesa 92 can be formed on a GaAs substrate 130 to bear the quantum subsystems 220, 220′. The structure is shown enlarged in FIG. 8a. Fine gates can be used to interface with the conductors.

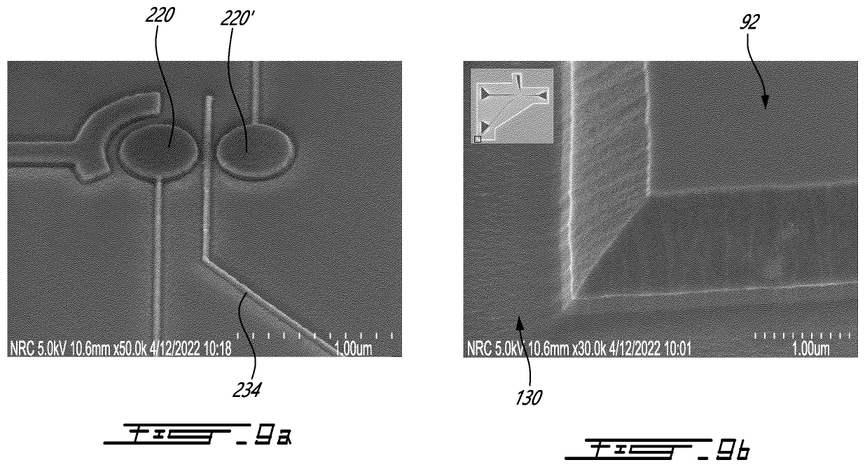

FIG. 9a presents metallic gates such as can be used to create and control a double quantum dot in accordance with an embodiment such as schematized in the inset of FIG. 8a. In this embodiment, the quantum system has two quantum subsystems 220, 220′ in the form of a pair of quantum dots. The two circular gates are plunger gates that define and control the dots while the thin middle gate 221 controls the tunnel coupling between the two dots, and can therefore be said to act as a coupler configured to control the interaction step. Finally, the leftmost gate is connected to a superconducting resonator used for charge sensing (measuring step, or readout). The heterostructure presented in FIG. 9 was fabricated by molecular beam epitaxy. In other embodiments, other fabrication techniques may be used, such as other vapor phase epitaxial growth techniques for instance.

In this embodiment, the presence of charges near the resonator can heavily impact the quality of the resonance. When shining light, charges are created under the resonator and stay trapped under the barrier, attracted by the Schottky potential. In this embodiment, to avoid this problem, the heterostructure is etched under the resonator as can be understood from the schematic presented in FIG. 8. The heterostructure is kept only at the position of the double dot, as depicted in FIG. 9b). The mesa edge can be seen in white around the device in the inset figure.

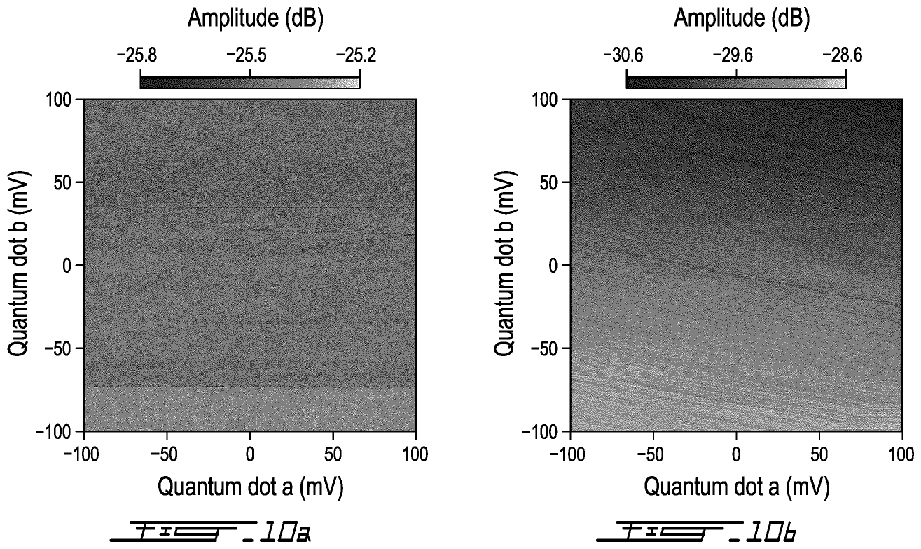

The device is adhered to a PCB 72 and encapsulated in a microwave cavity 62 used to isolate the device 64 from unwanted microwave frequencies. Once the device 64 is cooled down to ˜10 mK, a first stability diagram is measured. FIG. 10a) shows this measurement. No significant change in the resonator transmission is observed. This indicates that there are no free charges able to transition into and out from of the dots, as expected since there is no actively introduced doping (surface dopants).

Then, a first illumination (preparation 108, and more specifically separation step 110 referring to FIG. 2) is performed. Since the band gap of GaAs is 1.519 eV (816 nm), we shine a low-power, 785 nm laser (having an energy above the energy difference of the band gap) for 10 s through a small pinhole 68 in the microwave cavity 62, above the double dot. The amount of photons reaching the device is estimated to be ˜1×10\hat{ }12 every second. Some of these photons will reach the mesa 92 and create electron-hole pairs in the GaAs.

FIG. 10b) shows the same stability diagram as in a), but after the first illumination. Now, many lines of reduced resonator transmission are visible. Those lines are caused by charges transitioning in and out of the dots. This result proves that light can indeed create free charges that can be captured in the dots, and then manipulated without getting lost.

Once the charges are created, it is also possible to get rid of them, effectively resetting the device. Indeed, a band structure such as shown in FIG. 3b can be achieved by applying a strong bias to a metallic gate, which can invert a band structure from the configuration of FIG. 3a into a configuration such as shown in FIG. 3b (or vice versa), thus losing the confinement potential for charges, which can have the effect of evacuating charges. As we can see, upon applying the bias, the hole confinement potential is lost, and the charges can be evacuated or recombined.

This behaviour has been observed experimentally. When applying 1 V to all the gates for 30 s, all the charges would get lost. Measuring a stability diagram shows no more transition, similar to the diagram in FIG. 10a).

At this point, a new illumination can be performed and transitions such as shown in FIG. 10b) will become visible subsequently to the new illumination. Accordingly, the device can be reset using an electromagnetic field, without the need for a thermal cycle, and the result can be reproducible across different illumination processes.

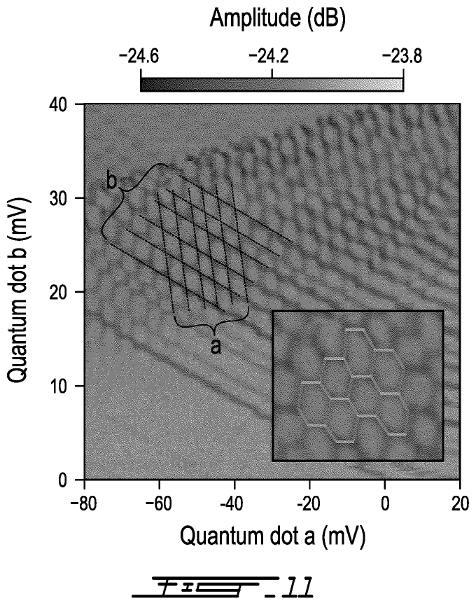

So far, the transitions that were observed are from a single quantum dot. By operating the device in a different regime, which can involve decreasing the coupling between the two dots, it is possible to reach a double quantum dot system. FIG. 11 presents a stability diagram in this regime. In this example, the illumination was performed with all three gates at OV and then applying 1V to the middle gate. The positive bias can increase the tunnel barrier height, and decrease the coupling.

A honeycomb pattern is visible, which is characteristic of a device operating as a double quantum dot. There are three different types of transitions visible. The addition lines for each dot are indicated by the dashed lines, while the third type of line corresponds to the interdot transition. All three types are illustrated in the inset figure with different colors.

Such a double quantum dot can be used in quantum computing using the principle of the location of the charge for instance. Indeed, a charge exhibiting quantum properties may be allowed to travel between the quantum dots, and the location of the charge may be determined using the resonator.

This result shows that it is possible to initialize quantum dots without the need for reservoirs, source/drain bias, ohmic contacts or doping. Therefore it is possible to reduce the footprint of the quantum dots at the surface of the semiconductor, allowing more space for important structures such as the dots themselves, but also for sensing tools and coupling gates.

Indeed, by shining an above-the-gap laser light onto an undoped GaAs substrate, it is possible to create and separate electron-hole pairs to form quantum dots with one of the two polarities. By pairing this technique with a superconducting coplanar waveguide resonator for the charge readout, a working many-charge double quantum dot device with controllable interdot charge exchange can be achieved.

In the latter example embodiment, the device can have only two plunger gates and one tunnel coupling gate, providing an embodiment where the initialization of quantum dots does not require reservoirs, source/drain bias, ohmic contacts, nor doping. Therefore, the number of gates may be reduced and the fabrication process may be simplified.

Moreover, this new method can be applied to a wide range of semiconductor quantum dot systems.

Such a hybrid device can constitute a first step towards a more scalable design for quantum dot arrays. It can also constitute a good starting point for quantum transduction due to the availability of optical-matter-microwave interaction.

It will be understood that the example presented above is provided solely for the purpose of providing one of numerous possible examples and also a demonstration that the concept can work at least in this example. Various other embodiments are possible and it is believed that the concept can work in at least some of such other embodiments, as explained below.

Indeed, while spatial-based quantum dot computer configurations are possible, such as can be based on the position of an electron in a double quantum dot, spin-based quantum dot computer configurations are also possible, wherein the qubit can be based on the spin states of trapped electrons. Spin-based quantum dot computer configurations are sometimes referred to as the Loss-DiVincenzo quantum computer in the art. In spin-based quantum dot computers, each qubit may be associated to a single quantum dot.

Various quantum dot architectures are possible. Gate-defined quantum dots are a family of several quantum dot architectures which is characterized by the presence of a semiconductor channel where the confinement potential is generated at least partially by a voltage applied on a “gate”. A gate is a metallic element located proximate the quantum dot and capacitively coupled to the quantum dot. The gate can be used to control the number of charges in the quantum dot. Gate-defined quantum dots include lateral quantum dots, vertical quantum dots, accumulation-based quantum dots, depletion-based quantum dots, crossbar arrays, strain induced quantum dots, hut wire quantum dots, and corner quantum dots, to name some examples. However, other types of quantum dot architectures than gate-defined quantum dots exist, such as self-assembled quantum dots and defect/dopant based quantum dots. The concept of separating the charges with electromagnetic waves is applicable to many quantum dot architectures, but may be easier to apply to some quantum dot architectures than others.

Lateral quantum dots, for instance, are groups of quantum dots which are positioned adjacent one another within a same plane. They can be aligned in a 1D array (e.g. a line), or in a 2D array. Lateral quantum dots appear to be an excellent candidate for applying the process of separating the charges using electromagnetic waves since, in principle, each quantum dot is accessible to electromagnetic waves via a common face of the plane.

Accumulation-based quantum dots refer to quantum dots where the trapped charges are located directly below a metallic gate. The process of separating the charges using electromagnetic waves can be applied to accumulation-based quantum dots as long as the electromagnetic wave is able to penetrate across the gate into the semiconductor material. This may require limiting the thickness of the metallic gates, for instance, and/or increasing the intensity of the electromagnetic radiation.

Depletion-based quantum dots refer to quantum dots where the trapped charges are located between metallic gates. The process of separating the charges using electromagnetic waves can be applied to this type of architecture in some embodiments. However, care may need to be taken to avoid accumulation of undesirable charges beneath the gates. Indeed, since electromagnetic radiation can generate both types of charges, and that tension on the gates attract the charge opposite to the one which is intended to become trapped for use in quantum computing, the opposite charges may interfere with the process if care is not taken to avoid or mitigate this effect.

Crossbar arrays constitute an approach to form a network of quantum dots in which each quantum dot can be independently addressed. To apply the process of separating charges using electromagnetic waves to crossbar array architecture, care may need to be taken to avoid or mitigate the undesirable presence of opposite charges in certain areas.

Strain-induced quantum dots constitute an approach to form a quantum dot via deformation of the crystalline structure of the channel at low temperatures. Strain-induced quantum dots appear to constitute a good candidate to apply a process of separating charges with electromagnetic waves in a manner comparable to the example presented above.

Self-assembled quantum dots refer to an approach where quantum dots are formed somewhat randomly during a minutely controlled growth phase of the device. The nature of self-assembled quantum dots can make them difficult to interface them to a source and to a drain, and the approach of preparing the charges via electromagnetic wave application may constitute a significant advantage over an approach of preparing the charges via gates, source and drain.

Defect and/or dopant based quantum dots refer to a relatively broad category of quantum dots where imperfections act as traps for the charges. The process of preparing the charges via electromagnetic wave application may conveniently apply to a large number of embodiments within this category.

It will be understood that the way the processes of initializing, interacting, measuring, and resetting are effected in a given embodiment will depend on the type of architecture of the embodiment.

Initializing, for instance, can be performed differently for charge qubits than for spin qubits. In the case of charge qubits, initializing typically involve adjusting the potentials of the quantum dots in a manner to limit the presence of charges to one, or the other, but not both, of the quantum dots of the quantum dot pair. The state corresponding to 0 or to 1 can correspond to the charge being in one, or the other, of the quantum dots of the pair.

In the case of spin qubits, it is relatively common to use a technique referred to as thermal relaxation to initialize. The thermal relaxation technique typically involves allowing a period of time to elapse before proceeding with the interaction. This period of time can be selected in a manner for it to be considered sufficiently long for the spin to reach the lowest energy level, which can naturally occur over time.

Interacting, for instance, can be performed differently depending on the quantum subsystem architecture. In perhaps a simplest case, two quantum dots can be coupled by proximity, e.g. by being sufficiently close to one another for charges to have the opportunity to pass from one to the other via quantum tunneling. In this manner, the spins can also be coupled. In the most basic expression of this approach, there is no mechanism provided to allow active control of the intensity of the coupling or of the rate of tunnelling. This type of approach is used in quantum annealing architectures. Another approach which involves active control of the interacting is by proximity, but via a control gate. By adding a control gate (e.g. metallic) between the two quantum dots, it is possible to change the “height” of the quantum tunnelling barrier which separates the two quantum dots, which can allow to control whether the charges are coupled and whether they can transition. Still another approach which also involves active control of the interacting is via a resonator. Indeed, distant quantum dots can be coupled to a same resonator, which allows to couple the quantum dots to one another since the resonator can be of variable size, typically within the resonator range. While electromagnetic radiation may interfere with the functioning of a resonator, such issues can be addressed, at least to a certain extent, by careful selection of the heterostructure at the basis of the device.

Measuring can also be performed differently depending on the quantum subsystem architecture. One approach to measuring is the use of a resonator (e.g. a method inspired by CQED). Indeed, by using a resonator in proximity to the quantum dot, it can be possible to detect transitions of charges in the dot by a change in the resonance frequency and/or a change in the amplitude of the peak of resonance of the system, and the frequency of the resonator depends of the capacity. While electromagnetic radiation may interfere with the functioning of a resonator, such issues can be addressed, at least to a certain extent, by careful selection of the heterostructure at the basis of the device. Another approach to measuring is the use of quantum point contact (QPC). This can be embodied as a circuit in proximity to the quantum dot wherein the transport properties change as a function of the number of charges in the quantum dot. There may be challenges associated to the use of quantum point contact in some embodiments using electromagnetic waves to perform the separation of the charges, and it may be preferred to use another measuring method is such embodiments. Another approach to measuring is the use of a single electron transistor (SET). This can be embodied in the form of an additional quantum dot (a) placed in proximity with the quantum dot (b) which is intended to be measured (read out). The presence or absence of a charge in the quantum dot b can have an impact on the properties of the electronic transport through the quantum dot a. By observing, say, the change in current, it is possible to detect the addition or withdrawal of a charge from the quantum dot b. There may be challenges associated to the use of single electron transistor in some embodiments using electromagnetic waves to perform the separation of the charges, and it may be preferred to use another measuring method is such embodiments. Still another approach to measuring is to use transport. In accordance with this latter approach, a current can be passed across a quantum dot as a function of tension applied to the gate controlling it. This can trigger sudden increases of current when charges can transition. One of the advantages of using light in this context is that it can reduce the footprint associated to transport at the surface of the device.

Resetting may apply in a manner similar to the one presented above in many embodiments of gate-based architecture quantum dots. Indeed, the closest the gate is to the quantum dot, the most efficient the resetting process can be, because it may require a lower potential to repel the undesired charges. Accordingly, resetting may be easier to apply to accumulation-based quantum dots that to depletion-based quantum dots.

It will be understood that the expression “computer” as used herein is not to be interpreted in a limiting manner. It is rather used in a broad sense to generally refer to the combination of some form of one or more processing units and some form of memory system accessible by the processing unit(s). The memory system can be of the non-transitory type. The use of the expression “computer” in its singular form as used herein includes within its scope the combination of a two or more computers working collaboratively to perform a given function. Moreover, the expression “computer” as used herein includes within its scope the use of partial capabilities of a given processing unit. Example computers include supercomputers, desktop, laptop, smartphone, smart watch, less elaborated controller devices, etc.

A processing unit can be embodied in the form of a general-purpose micro-processor or microcontroller, a digital signal processing (DSP) processor, an integrated circuit, a field programmable gate array (FPGA), a reconfigurable processor, a programmable read-only memory (PROM), to name a few examples.

The memory system can include a suitable combination of any suitable type of computer-readable memory located either internally, externally, and accessible by the processor in a wired or wireless manner, either directly or over a network such as the Internet. A computer-readable memory can be embodied in the form of random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) to name a few examples.

A computer can have one or more input/output (I/O) interface to allow communication with a human user and/or with another computer via an associated input, output, or input/output device such as a keyboard, a mouse, a touchscreen, an antenna, a port, etc. Each I/O interface can enable the computer to communicate and/or exchange data with other components, to access and connect to network resources, to serve applications, and/or perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, Bluetooth, WiMAX), SS7 signaling network, fixed line, local area network, wide area network, to name a few examples.

It will be understood that a computer can perform functions or processes via hardware or a combination of both hardware and software. For example, hardware can include logic gates included as part of a silicon chip of a processor. Software (e.g. application, process) can be in the form of data such as computer-readable instructions stored in a non-transitory computer-readable memory accessible by one or more processing units. With respect to a computer or a processing unit, the expression “configured to” relates to the presence of hardware or a combination of hardware and software which is operable to perform the associated functions. Different elements of a computer, such as processor and/or memory, can be local, or in part or in whole remote and/or distributed and/or virtual.

The methods and systems of the present disclosure may be implemented in a high level procedural or object oriented programming or scripting language, or a combination thereof, to communicate with or assist in the operation of a computer system, for example the controller. Alternatively, the methods and systems described herein may be implemented in assembly or machine language. The language may be a compiled or interpreted language. Program code for implementing the methods and systems described herein may be stored on a storage media or a device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein. Embodiments of the methods and systems described herein may also be considered to be implemented by way of a non-transitory computer-readable storage medium having a computer program stored thereon. The computer program may comprise computer-readable instructions which cause a computer, or more specifically the processing unit of the computing device, to operate in a specific and predefined manner to perform the functions described herein.

Computer-executable instructions may be in many forms, including program modules, executed by one or more computers or other devices. Generally, program modules include routines, programs, objects, components, data structures, etc., that perform particular tasks or implement particular abstract data types. Typically the functionality of the program modules may be combined or distributed as desired in various embodiments. The technical solution of embodiments may be in the form of a software product. The software product may be stored in a non-volatile or non-transitory storage medium, which can be a compact disk read-only memory (CD-ROM), a USB flash disk, or a removable hard disk. The software product includes a number of instructions that enable a computer device (personal computer, server, or network device) to execute the methods provided by the embodiments.

The embodiments described herein are implemented by physical computer hardware, including computing devices, servers, receivers, transmitters, processors, memory, displays, and networks. The embodiments described herein provide useful physical machines and particularly configured computer hardware arrangements. The embodiments described herein are directed to electronic machines and methods implemented by electronic machines adapted for processing and transforming electromagnetic signals which represent various types of information. The embodiments described herein pervasively and integrally relate to machines, and their uses; and the embodiments described herein have no meaning or practical applicability outside their use with computer hardware, machines, and various hardware components. Substituting the physical hardware particularly configured to implement various acts for non-physical hardware, using mental steps for example, may substantially affect the way the embodiments work. Such computer hardware limitations are clearly essential elements of the embodiments described herein, and they cannot be omitted or substituted for mental means without having a material effect on the operation and structure of the embodiments described herein. The computer hardware is essential to implement the various embodiments described herein and is not merely used to perform steps expeditiously and in an efficient manner.

As can be understood, the examples described above and illustrated are intended to be exemplary only. The scope is indicated by the appended claims.

What is claimed is:

1. A method of performing a quantum computation comprising:
providing a semiconductor material having a band gap associated to an energy difference;
preparing a first quantum dot, including
propagating an electromagnetic wave having an energy greater than the energy difference into the semiconductor material, the electromagnetic wave separating an electron of the semiconductor material from a hole of the semiconductor material in the presence of an electromagnetic field, the electromagnetic field maintaining the electron separated from the hole, and maintaining at least one of the separated electron and the separated hole confined within the semiconductor material;
the first quantum dot engaging in a quantum interaction with a second quantum dot; and
measuring a quantum state of the first quantum dot and of the second quantum dot.

2. The method of claim 1 further comprising a deep donor dopant provided within the semiconductor material generating the electromagnetic field.

3. The method of claim 1 further comprising applying an electric potential at a gate in capacitive contact with the semiconductor material, the gate generating the electromagnetic field.

4. The method of claim 3 further comprising, subsequently to said measuring, interrupting the electric potential at the gate, and thereby interrupting the electromagnetic field.

5. The method of claim 1 wherein said separating includes separating at least one electron of the semiconductor from at least one hole of the semiconductor material, wherein one of the at least one electron and of the at least one hole is a charge engaged in the quantum interaction.

6. The method of claim 1 wherein said separating includes separating a plurality of electrons of the semiconductor from a plurality of holes of the semiconductor material, further comprising evacuating at least one of the plurality of electrons and/or at least one of the plurality of holes from the semiconductor prior to maintaining at least one of a remainder of the plurality of electrons and a remainder of the plurality of holes confined within the semiconductor material, wherein one of a remainder of the plurality of electrons and a remainder of the plurality of holes is a charge engaged in the quantum interaction.

7. The method of claim 1 further comprising, subsequently to said measuring, applying an electric potential at a gate in capacitive contact with the semiconductor material, the gate generating a second electromagnetic field, the second electromagnetic field interrupting at least one of said maintaining the electron separated from the hole and said maintaining at least one of the separated electron and the separated hold confined within the semiconductor material and thereby resetting the first quantum dot.

8. The method of claim 1 further comprising initializing one of the separated electron and the separated hole as a charge of the first quantum dot, said initializing including allowing a period of time to pass, the period of time associated to a thermal relaxation period subsequently to which a spin of the charge is expected to have reached a lowest energy state.

9. The method of claim 1 wherein the first quantum dot is one of two quantum dots of a quantum dot pair, further comprising initializing one of the separated electron and the separated hole as a charge of the quantum dot pair, wherein said initializing includes ensuring an absence of the corresponding one of the separated electron and the separated hole in the other quantum dot of the quantum dot pair.

10. The method of claim 1 wherein said engaging in a quantum interaction includes actively reducing a quantum tunnelling barrier between the first quantum dot and the second quantum dot to promote the quantum interaction.

11. The method of claim 1 further comprising preparing the second quantum dot prior to said engaging in a quantum interaction, the second quantum dot having a semiconductor material having a band gap associated to an energy difference, including
propagating an electromagnetic wave having an energy greater than the energy difference into the semiconductor material, the electromagnetic wave separating an electron of the semiconductor material from a hole of the semiconductor material in the presence of an electromagnetic field;
the electromagnetic field maintaining the electron separated from the hole;
maintaining at least one of the separated electron and the separated hole confined within the semiconductor material.

12. The method of claim 11 wherein said first quantum dot and said second quantum dot are located within a same plane, the plane having two opposite faces, and said propagating includes propagating the electromagnetic waves onto a same one of said faces for the first quantum dot and the second quantum dot.

13. A system comprising:
a semiconductor material having a band gap associated to an energy difference, the semiconductor material having at least a first quantum dot region and a second quantum dot region, the semiconductor material having a planar geometry;
a confinement barrier covering both the first quantum dot region and the second quantum dot region;
an emitter subsystem configured for emitting an electromagnetic wave having an energy greater than the energy difference into the semiconductor material, at the first quantum dot region and at the second quantum dot region, across the confinement barrier;
means of sustaining an electromagnetic field in both the first quantum dot region and the second quantum dot region;
a quantum tunneling barrier between the first quantum dot region and the second quantum dot region;
means of measuring a quantum state of the first quantum dot region and of the second quantum dot region.

14. The system of claim 13 wherein the means of sustaining an electromagnetic field includes electrostatic contacts associated to the first quantum dot region and the second quantum dot region.

15. The system of claim 13 wherein the means of sustaining an electromagnetic field includes a deep donor dopant forming part of the semiconductor material.

16. The system of claim 13 wherein the first quantum dot region and the second quantum dot region are coupled neither to a source nor to a drain.

17. The system of claim 13 wherein further comprising at least one gate capacitively coupled to the first quantum dot region and at least one gate capacitively coupled to the second quantum dot region.

18. The system of claim 13 enclosed in a refrigerator operable to temperatures of below 100K, below 50K, or below 10K, further comprising a controller connected to the emitter system and to the means of measuring across a wall of the refrigerator.
